(19) United States
(12) Patent Application Publication
(10) Pub. No.: US 2023/0188091 A1
(43) Pub. Date: Jun. 15, 2023

(54) METHOD AND APPARATUS FOR DIAGNOSING PHOTOVOLTAIC PANEL FAULTS

(71) Applicant: POSTECH Research and Business Development Foundation, Pohang-si (KR)

(72) Inventors: Young Jin KIM, Pohang si (KR); Ji Hun HA, Uljin-gun (KR)

(73) Assignee: POSTECH Research and Business Development Foundation, Pohang-si (KR)

(21) Appl. No.: 18/079,844

(22) Filed: Dec. 12, 2022

(30) Foreign Application Priority Data
Dec. 13, 2021 (KR) 10-2021-0177450

(51) Int. Cl. H02S 50/10; G06F 30/20

(52) U.S. Cl. CPC H02S 50/10; G06F 30/20

(57) ABSTRACT

A photovoltaic panel fault diagnosis method using a fault diagnosis algorithm in a photovoltaic system comprises modeling a photovoltaic system simulation model necessary for the fault diagnosis algorithm, defining fault scenarios and pre-processing through data normalization after creating and acquiring fault data in advance using the photovoltaic system simulation model, and utilizing scenario-specific fault data obtained through the data normalization with a machine learning method.

### CROSS-REFERENCE TO RELATED APPLICATIONS

This application claims priority to Korean Patent Application No. 10-2021-0177450, filed on Dec. 13, 2021 with the Korean Intellectual Property Office (KIPO), the entire contents of which are hereby incorporated by reference.

### BACKGROUND

### 1. Technical Field

The present disclosure relates to a method and apparatus for diagnosing photovoltaic panel faults using a maximum power voltage and a maximum power current in a photovoltaic system.

### 2. Related Art

Recently, as the global warming problem has become serious due to fossil fuels and greenhouse gases, interest and demand for eco-friendly power generation, i.e., renewable energy, is increasing worldwide. In this situation, photovoltaics (PV) is attracting attention as one of the alternatives to solve serious environmental problems. In fact, according to the data announced by the International Trade Research Institute of the Korea International Trade Association, the share of solar power among new renewable energy facilities in the world accounted for 54% or more than half of the total, and the investment scale also recorded 44.8% of the global renewable energy investment.

However, the photovoltaic system, which is currently established as an important renewable energy source, is vulnerable to faults and at the same time has difficulty detecting or classifying faults. In order to solve this problem, various methods of fault diagnosis algorithms are being discussed. Most papers are only concerned with diagnosing and classifying a small number of faults or judging only the presence or absence of faults.

Further, researches on model-based fault diagnosis methods and machine learning-based fault diagnosis algorithms have been actively conducted. In particular, in existing papers using both methods simultaneously, an actual photovoltaic system requires an additional reference module and a current-voltage (I-V) characteristic curve measuring device for fault diagnosis. However, it is necessary to assume that the reference module does not fail, and there is a large measurement error in the actual I-V characteristic curve measuring device. This eventually leads to an increase in fault diagnosis and management costs.

### SUMMARY

In order to solve the above problems, the present disclosure provides a photovoltaic panel fault diagnosis apparatus and a method capable of diagnosing faults using a fault diagnosis algorithm without a reference module and an I-V characteristic curve measuring device.

Further, in order to solve the above problems, the present disclosure provides a photovoltaic panel fault diagnosis method and an apparatus using a fault diagnosis model that utilizes a maximum power voltage and a maximum power current determined in advance through a simulation model in photovoltaic systems.

According to a first exemplary embodiment of the present disclosure, a photovoltaic fault diagnosis method comprises: acquiring insolation of the photovoltaic system and temperature of the photovoltaic module; obtaining first data including a maximum power voltage in a steady state and a maximum power current in a steady state by inputting the amount of solar radiation and the temperature of the photovoltaic module into a simulation model; obtaining second data including a real-time maximum power voltage and a real-time maximum power current through maximum power point tracking of the photovoltaic system; normalizing the second data by utilizing the first data; and diagnosing a fault type of the photovoltaic system by inputting the normalized data into a fault diagnosis model.

The method further comprises generating the simulation model, wherein the generating of the simulation model comprises selecting a one-diode model that reduces the difference between the I-V characteristic curve value of the actual solar module and the I-V characteristic curve value of the simulation model; and performing parameter estimation for a series resistance and a parallel resistance in an equivalent circuit of an actual photovoltaic device including the series resistance and the parallel resistance connected to the one-diode model.

According to a second exemplary embodiment of the present disclosure, a photovoltaic fault diagnosis apparatus comprises: a processor; and a memory configured to store a program command executed by the processor, wherein, when the program command is executed by the processor, the program command is executed such that the processor performs: acquiring insolation of the photovoltaic system and temperature of the photovoltaic module; obtaining first data including a maximum power voltage in a steady state and a maximum power current in a steady state by inputting the amount of solar radiation and the temperature of the photovoltaic module into a simulation model; obtaining second data including a real-time maximum power voltage and a real-time maximum power current through maximum power point tracking of the photovoltaic system; normalizing the second data by utilizing the first data; and diagnosing a fault type of the photovoltaic system by inputting the normalized data into a fault diagnosis model.

The processor may further perform generating the simulation model, wherein the generating of the simulation model comprises selecting a one-diode model that reduces the difference between the I-V characteristic curve value of the actual solar module and the I-V characteristic curve value of the simulation model; and performing parameter estimation for a series resistance and a parallel resistance in an equivalent circuit of an actual photovoltaic device including the series resistance and the parallel resistance connected to the one-diode model.

The obtaining of the first data may be performed to obtain based on a fault condition of a predetermined fault scenario for the photovoltaic system through the simulation model.

The fault condition may include solar radiation at intervals of several tens W/m² in the range of 0 to 1,000 W/m² and solar module temperatures at predetermined temperature intervals in the range of 10° C. to 60° C.

The obtaining of the normalized data may utilize a maximum power voltage and a maximum power current obtained from maximum power point tracking through a converter installed in the photovoltaic system.

The obtaining of the normalized data may include obtaining a normalized voltage by dividing the maximum power voltage by an open circuit voltage in a steady state of the photovoltaic system; and obtaining a normalized current by dividing the maximum power current by a short circuit current in a normal state of the photovoltaic system.

The fault diagnosis model may be generated through machine learning based on the normalized voltage and the normalized current calculated according to a preset fault scenario for the photovoltaic system.

According to a third exemplary embodiment of the present disclosure, a photovoltaic panel fault diagnosis apparatus, which uses a fault diagnosis algorithm with only a maximum power point voltage (V_{MPP}) and a maximum power point current (I_{MPP}) in a photovoltaic system, may comprise: a processor; and a memory configured to store at least one instruction executed by the processor, wherein the at least one instruction is executed by the processor to perform: modeling a photovoltaic system simulation model necessary for the fault diagnosis algorithm; defining fault scenarios and pre-processing through data normalization after creating and acquiring fault data in advance using the photovoltaic system simulation model; and utilizing scenario-specific fault data obtained through the data normalization with a machine learning method.

One-diode model using one diode may be selected by a photovoltaic module simulation model similar to the actual photovoltaic module using a model-based fault diagnosis algorithm.

A parameter estimation method may be used to improve accuracy of the simulation model by reducing an error between a current-voltage (I-V) characteristic curve value of the actual photovoltaic module and an I-V characteristic curve value of the simulation model.

A series resistance (RS) and a parallel resistance (RP) may be estimated using a Villava's method, and fault data may be created and acquired with the photovoltaic module simulation model obtained through parameter estimation.

A fault scenario may be determined in advance to generate fault data, wherein the fault scenario is based on consideration of various fault conditions including a wide range of solar radiation (from 0 W/M2 to 1,000 W/M2, 40 W/M2 intervals) and temperature (10° C. to 60° C., 5° C. intervals) and input as an input value to a photovoltaic simulation to output data, which normalized for use in the fault diagnosis. The temperature can be replaced by Kelvin temperature.

According to a fourth exemplary embodiment of the present disclosure, a photovoltaic panel fault diagnosis method using a fault diagnosis algorithm with a maximum power point voltage (V_{MPP}) and a maximum power point current (I_{MPP}) in a photovoltaic system may comprise: modeling a photovoltaic system simulation model necessary for the fault diagnosis algorithm; defining fault scenarios and pre-processing through data normalization after creating and acquiring fault data in advance using the photovoltaic system simulation model; and utilizing scenario-specific fault data obtained through the data normalization with a machine learning method.

The method may further comprise an offline process comprising: defining the fault scenarios and creating and acquiring fault data after creating a simulation model identical in output to the actual photovoltaic system; and creating a power generation system fault diagnosis model using a machine learning method with the data obtained through the data normalization.

The method may further comprise an online process comprising: obtaining the maximum power point voltage (V_{MPP,N}) and maximum power point current (I_{MPP,N}) in a normal state by inputting a value measured by a solar radiation and module temperature sensor installed in the actual photovoltaic system to a previously created model; obtaining simultaneously a real-time maximum power point voltage (V_{MPP,F}) and maximum power point current (I_{MPP,F}) through a maximum power point tracking technique installed in a converter of the actual photovoltaic system; and diagnosing a fault by inputting data acquired by normalizing the obtained data to the fault diagnosis model created in the offline process.

The photovoltaic panel fault diagnosis apparatus according to an embodiment of the present disclosure provides an algorithm for diagnosing a fault with the maximum power point voltage (V_{MPP,F}) and the maximum power point current (I_{MPP,F}) in the actual photovoltaic system based on the photovoltaic simulation model.

To this end, a simulation model may be developed using the parameter estimation method to obtain the same value as the output value of the actual photovoltaic system.

Afterward, in order to make a robust fault diagnosis algorithm in any environment, various fault scenarios may be selected and the fault data may be obtained through the simulation model is normalized.

The normalized data may be used as input data to a machine learning (e.g., K-Nearest Neighbor, k-NN)-based fault diagnosis model for training.

After this pre-processing, the actual photovoltaic system receives the solar radiation quantity and solar module temperature and put them as input values in the simulation to obtain the steady-state maximum power point voltage (V_{MPP, N}) and the steady-state maximum power point current (I_{MPP,N}).

After being simultaneously obtained from the actual photovoltaic system, the maximum power point voltage (V_{MPP,F}) and maximum power point current (I_{MPP,F}) are normalized and then put into the existing machine learning-based fault diagnosis model to show the type of fault.

### BRIEF DESCRIPTION OF DRAWINGS

FIG. 1 is a schematic diagram illustrating a fault diagnosis algorithm using a maximum power point voltage and a maximum power point current in a photovoltaic system of a photovoltaic panel fault diagnosis apparatus according to an embodiment of the present disclosure.

FIG. 2 is a schematic diagram illustrating simulation modeling and pre-processing of a photovoltaic panel fault diagnosis apparatus according to an embodiment of the present disclosure.

FIG. 3 is a conceptual diagram illustrating a comparison between an existing method and a proposed method in data normalization.

FIG. 4 is a process flow diagram illustrating a fault diagnosis algorithm using maximum power point voltage and maximum power point current after simulation modeling and pre-processing a photovoltaic panel fault diagnosis apparatus according to an embodiment of the present disclosure.

FIG. 5 is a schematic diagram illustrating a MATLAB/Simulink photovoltaic system simulation model of a 5×3 structure as a test bed to which an algorithm of a photovoltaic panel fault diagnosis apparatus according to an embodiment of the present disclosure is applied and fault types.

FIG. 6 is a graph of normal and faulty maximum power point voltage (Vmpp) and maximum power point current (Impp) data for various fault scenarios before normalization at the photovoltaic panel fault diagnosis apparatus according to an embodiment of the present disclosure.

FIG. 7 is a graph of normal and faulty maximum power point voltage (Vmpp) and maximum power point current (Impp) data for various fault scenarios after normalization through the conventional method.

FIG. 8 is a graph of normal and faulty maximum power point voltage (Vmpp) and maximum power point current (Impp) data for various fault scenarios after normalization through a photovoltaic panel fault diagnosis method according to an embodiment of the present disclosure.

FIG. 9 is a block diagram illustrating a photovoltaic panel fault diagnosis apparatus 1000 according to an embodiment of the present disclosure.

### DETAILED DESCRIPTION OF THE EMBODIMENTS

Exemplary embodiments of the present disclosure are disclosed herein. However, specific structural and functional details disclosed herein are merely representative for purposes of describing exemplary embodiments of the present disclosure. Thus, exemplary embodiments of the present disclosure may be embodied in many alternate forms and should not be construed as limited to exemplary embodiments of the present disclosure set forth herein.

Accordingly, while the present disclosure is capable of various modifications and alternative forms, specific exemplary embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular exemplary embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. For example, the term of “fault” is replaced with the term of “failure”

Hereinafter, exemplary embodiments of the present disclosure will be described in greater detail with reference to the accompanying drawings. In order to facilitate general understanding in describing the present disclosure, the same components in the drawings are denoted with the same reference signs, and repeated description thereof will be omitted.

The photovoltaic panel fault diagnosis method according to an embodiment of the present disclosure proposes a fault diagnosis algorithm using only the maximum power point voltage (Vₘₚₚ) and the maximum power point current (Iₘₚₚ) in the photovoltaic system. In other words, the first step is to model a photovoltaic system simulation model required for the fault diagnosis algorithm using MATLAB/Simulink. The second step is to define fault scenarios, generate and acquire fault data in advance using the MATLAB/Simulink photovoltaic system simulation model, and then perform pre-processing through data normalization. Furthermore, the third step is to use the machine learning (e.g., K-Nearest Neighbor, k-NN) method with scenario-specific fault data obtained through data normalization.

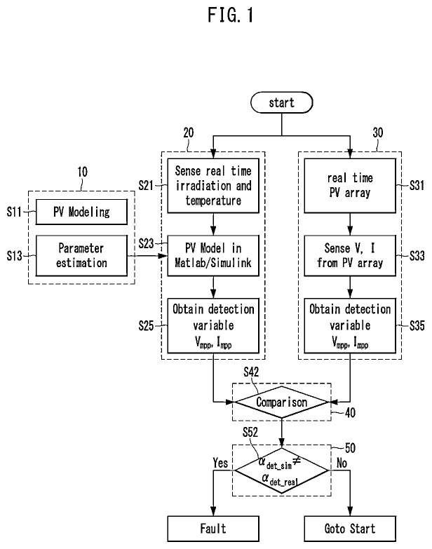

FIG. 1 is a schematic diagram illustrating a fault diagnosis algorithm using a maximum power point voltage and a maximum power point current in a photovoltaic system of a photovoltaic panel fault diagnosis apparatus according to an embodiment of the present disclosure.

With reference to FIG. 1, the fault diagnosis algorithm uses a maximum power point voltage (V_{MPP}) and a maximum power point current (I_{MPP}). The maximum power point voltage and the maximum power point current can be denoted as Vₘₚₚ and Iₘₚₚ, respectively.

The fault diagnosis algorithm using the maximum power point voltage and the maximum power point current in the photovoltaic system includes steps S11, S13, S21, S23, S25, S31, S33, S35, S42 and S52.

In a broad sense, the fault diagnosis algorithm can be composed of two processing phases consisting of a first processing phase of steps S11 and S13, and a second processing phase of steps S21, S23, S25, S31, S33, S35, S42 and S52.

Specifically, in the first processing phase, a first processing unit 10 may define a fault scenario to create a simulation model with output characteristic substantially identical to those of an actual photovoltaic system. Photovoltaic (PV) modeling for the simulation model can be performed through parameter estimation (S11, S13). The simulation model may include a MATLAB simulation model or a Simulink simulation model, and may be referred to as a simulation photovoltaic (PV) model. Then, the first processing unit 10 may create a fault diagnosis model using a machine learning method with the data obtained through a data normalization process.

In the second processing phase, a second processing unit 20 may obtain values of solar radiation measured by solar radiation sensors and values of temperature measured by module temperature sensors installed in the actual photovoltaic system (S21). The solar radiation may be referred as an irradiance. Then, the second processing unit 20 may input the values to the simulation model (S23) to obtain detection variables of a maximum power point voltage (Vₘₚₚ) and a maximum power point current (Iₘₚₚ). The detection variables of Vₘₚₚ and Iₘₚₚ may be referred to as a first maximum power point voltage (V_{MPP,N}) and a first maximum power point current (I_{MPP,N}), respectively. The first maximum power point voltage (V_{MPP,N}) and the first maximum power point current (I_{MPP,N}) corresponding to the detection variables of Vₘₚₚ and Iₘₚₚ obtained from the simulation model may be transferred to a pre-processing unit 40 (S25).

Simultaneously, a third processing unit 30 may obtain real time voltages and currents of a PV array by sensing voltages (V) and currents (I) in real time from the PV array of the actual photovoltaic system (S31, S33). The PV array may be included in a PV panel. Then, the third processing unit 30 may obtain a maximum power point voltage (Vₘₚₚ) and a maximum power point current (Iₘₚₚ) in real-time via the Maximum Power Point Tracking by a converter installed in the PV system (S35). The maximum power point voltage (Vₘₚₚ) and The maximum power point current (Iₘₚₚ) obtained in real-time from the convertor may be referred as a second maximum power point voltage (V_{MPP,N}) and a second maximum power point current (I_{MPP,F}), respectively. The second maximum power point voltage (V_{MPP,F}) and the second maximum power point current (I_{MPP,F}) may be transferred to a pre-processing unit 40 (S35).

The pre-processing unit 40 may compare the first maximum power point voltage (V_{MPP,N}) and the second maximum power point voltage (V_{MPP,F}), and the pre-processing unit 40 may also compare the first maximum power point current (I_{MPP,N}) and the second maximum power point current (I_{MPP,F}) (S42). Further, the pre-processing unit 40 may normalize the data obtained through the above comparative process. The normalized data may be transferred to the fault diagnosis model as inputs thereof.

Next, the fault diagnosis model 50 may diagnose the type of photovoltaic panel fault generated in the photovoltaic panel. The fault diagnosis model 50 may determine the type of PV fault based on whether a first data (α_{det_sim}) obtained from the simulation model and a second data (α_{det_real}) measured in real time are substantially the same or not (S52).

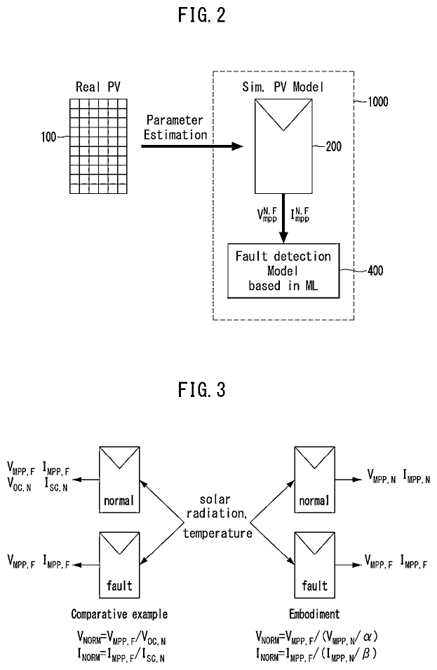

FIG. 2 is a schematic diagram illustrating simulation modeling and pre-processing of a photovoltaic panel fault diagnosis apparatus according to an embodiment of the present disclosure.

With reference to FIG. 2, the simulation modeling and pre-processing of the photovoltaic panel fault diagnosis apparatus according to an embodiment of the present disclosure shows the first processing phase in detail.

First, in a model-based fault diagnosis algorithm for a fault diagnosis apparatus 1000, a photovoltaic module simulation model 200 similar to the actual photovoltaic module 100 is required. A one-diode model using one diode may be selected as the photovoltaic module simulation model 200 for use in the embodiment of the present disclosure. The photovoltaic module simulation model may be shortly referred as the simulation model, a simulation PV, or a simulation PV model.

In order to improve the accuracy of the simulation model 200, it is necessary to reduce the error between the I-V characteristic curve value of the actual photovoltaic module 100 and the I-V characteristic curve value of the simulation model 200. Accordingly, a parameter estimation method may be used in the embodiment of the present disclosure.

The photovoltaic panel fault diagnosis apparatus according to an embodiment of the present disclosure may estimate a series resistance (RS) and a parallel resistance (RP) using Villalva's Method.

The photovoltaic panel fault diagnosis apparatus may generate and acquire fault data using the simulation model 200 optimized through parameter estimation.

In order to generate the fault data, a fault scenario must be determined first. In order to develop a fault diagnosis algorithm robust to any environment, a fault condition of the fault scenarios are based on the consideration of a wide range of solar radiation and temperature and various fault conditions. The temperature may include temperature measured by module temperature sensors installed in the PV panel having the PV array.

The fault condition may include solar radiations at intervals of several tens W/m² in the range of 0 to 1,000 W/m² and temperatures at predetermined intervals in the range of 10° C. to 60° C. The temperatures may be referred to as solar module temperatures, PV panel temperatures, or PV array temperatures. The intervals of the solar radiations may be preferably obtained with 40 W/M² intervals, and the intervals of the temperatures may be preferably obtained with 5° C. intervals.

The various fault conditions of the fault scenarios are shown in Table 1. The fault scenarios based on the consideration of the wide range of conditions are input to the simulation model as input values, and output data outputted from the simulation model may be normalized for use in a fault diagnosis model 400 based on a machine learning model. The fault diagnosis model 400 may be corresponded to the fault diagnosis model 50 shown in FIG. 1.

Table 1 shows various fault scenarios for the robust fault diagnosis algorithm.

TABLE 1

| | | Characteristic | | |
|---|---|---|---|---|
| Fault | | | | Resistance |
| Name | Fault Type | Fault Location | Mismatch | [Ω] |
| LL1 | Line-to-Line | Intra-String | 1 | 0 |
| | short circuit fault | | | 5 |
| | (with one LL fault) | | | 10 |
| LL2 | Line-to-line | Intra-String | 2 | 0 |
| | short circuit fault | | | 5 |
| | (with two LL faults) | | | 10 |
| OC1 | Open Circuit fault | String Open | 1 | — |
| | (with one OC fault) | | | |
| OC2 | Open Circuit fault | String Open | 2 | — |
| | (with two OC faults) | | | |
| PS | Partial Shading | Entire Array | — | — |

In a simulation mode, the photovoltaic panel fault diagnosis apparatus 1000 may generate the first data and the second data through the simulation model 200, and input the generated data to the fault diagnosis model 400. The fault diagnosis model 400 may include a fault detection model based in a machine learning (ML). The first data may include the first maximum power point voltage and the first maximum power point current, and the second data may include the second maximum power point voltage and the second maximum power point current. In FIG. 2, the first maximum power point voltage and the second maximum power point voltage are represented by Vₘₚₚ^{N,F} and the first maximum power point voltage and the second maximum power point voltage are represented by Iₘₚₚ^{N,F}.

FIG. 3 is a conceptual diagram illustrating a comparison between an existing method according to a comparative example and a proposed method according to the embodiment of the present disclosure in data normalization.

Referring to FIG. 3, the difference between the existing method and the proposed method in data normalization can be shown.

In the case of the existing method, data is normalized using Equations 1 and 2. Assuming that the normalized voltage is V_{NORM} and the normalized current is I_{NORM}, the normalized voltage is obtained by dividing the maximum power point voltage (V_{MPP,F}) by the steady-state open circuit voltage (V_{OC,N}), and the normalized current is obtained by dividing the maximum power point current (I_{MPP,F}) by the steady-state short circuit current (I_{SC,N}). After obtaining the normalized voltage and current, a fault diagnosis model is created through machine learning.

V_{NORM}=V_{MPP,F}÷V_{OC,N} [Equation 1]

I_{NORM}=I_{MPP,F}÷I_{SC,N} [Equation 2]

However, in the case of the existing method, when diagnosing an actual photovoltaic panel fault, it is necessary to install one reference photovoltaic module and obtain the open circuit voltage (V_{OC,N}) and the short circuit current (I_{SC,N}) in the normal state via an additionally installed photovoltaic I-V characteristic curve measuring device.

Due to this, two problems may be raised in the existing method.

First, the reference photovoltaic module not only incurs additional installation cost is installed but also must be guaranteed to be in a normal state to protect against an error occurring in data normalization.

Second, the additionally installed solar I-V characteristic curve measuring device incurs additional costs. When measuring the I-V characteristic curve at the actual photovoltaic power generation site, the solar module temperature and the solar radiation amount affect the I-V characteristic curve measurement significantly, resulting in measurement error. Particularly in the case of general products, when the measurement time takes more than a few seconds (average: 10 seconds) and the solar radiation amount fluctuates during the measurement period, there is a possibility that the measurement error increases. That is, the existing method is ineffective in terms of fault diagnosis and management costs.

Meanwhile, the proposed method adopted in the photovoltaic panel fault diagnosis apparatus according to an embodiment of the present disclosure uses the maximum power point voltage (V_{MPP,F}) and maximum power point current (I_{MPP,F}) acquired through the maximum power point tracking technique installed in the converter when obtaining the normalized voltage is V_{NORM} and the normalized current is I_{NORM}.

According to this, the proposed method may eliminate the need for an additional I-V characteristic curve measurement device. In addition, by using the simulation model that has output characteristics similar to those of a real photovoltaic system through parameter estimation, it is possible to solve the uncertainty problem of the reference photovoltaic module and furthermore reduce the fault diagnosis costs with the elimination of the reference photovoltaic module.

In particular, the relationships between the maximum power point voltage (V_{MPP}) and the open circuit voltage (V_{OC}) and between the maximum power point current (I_{MPP}) and the short circuit current (I_{SC}) may be defined as shown in Equations 3 and 4, respectively. Here, the maximum power point voltage (V_{MPP}) may be the first maximum power point voltage (V_{MPP,N}) and the maximum power point current (I_{MPP}) may be the first maximum power point current (I_{MPP,N}). Further, α and β are variables, and in the present disclosure, α is set to 0.8 and β is set to 0.9. Using this, Equation 1 and Equation 2 can be changed to Equation 5 and Equation 6, respectively.

V_{MPP}=α×V_{OC} [Equation 3]

I_{MPP}=β×I_{SC} [Equation 4]

V_{NORM}=V_{MPP,F}÷(V_{MPP,N}÷α) [Equation 5]

I_{NORM}=I_{MPP,F}÷(I_{MPP,N}÷β) [Equation 6]

In fact, the variable α can be calculated as the average of the first maximum power point voltages, and the variable β can be calculated as the average of the first maximum power point current. As a result of the calculation, variable α has a range of 7.8 to 8.2, and variable β has a range of 8.8 to 9.2. Accordingly, in this embodiment, it can be applied by setting the variable α to 8 and the variable b to 9.

As such, the proposed method may normalize the data using the maximum power point voltage (V_{MPP}) and the maximum power point current (I_{MPP}), and may input the data obtained through this as input values to a machine learning (e.g., K-Nearest Neighbor, k-NN)-based fault diagnosis model for training. The normalized voltage (V_{NORM}) and the normalized current (I_{NORM}) are the input values inputted to the fault diagnosis model.

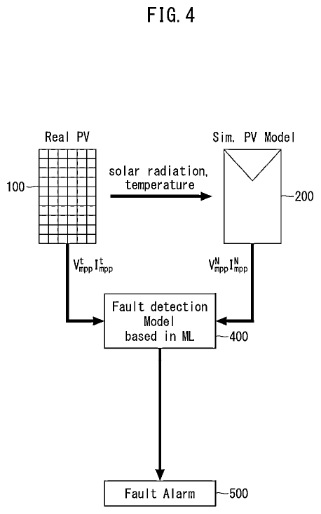

FIG. 4 is a process flow diagram illustrating a fault diagnosis algorithm using maximum power point voltage and maximum power point current after simulation modeling and pre-processing a photovoltaic panel fault diagnosis apparatus according to an embodiment of the present disclosure.

With reference to FIG. 4, the actual photovoltaic system 100 measures solar radiation and solar module temperature via a solar radiation sensor and a solar module temperature sensor. When measuring solar radiation and solar module temperature, the actual photovoltaic system 100 can measure the maximum power point voltage (Vₘₚₚ^{t}) and maximum power point current (Iₘₚₚ^{t}) at time t. The maximum power point voltage (Vₘₚₚ^{t}) and maximum power point current (Iₘₚₚ^{t}) may be denoted as the second maximum power point voltage (Vₘₚₚ) and the second maximum power point current (Iₘₚₚ) for convenience of illustration.

The simulation model 200 may be obtained values of solar radiation and solar module temperature at time t from the actual photovoltaic system 100. Specifically, the simulation model 200 may calculate the first maximum power point voltage (Vₘₚₚ^{N}) and the first maximum power point current (Iₘₚₚ^{N}) are collected in the normal state by simultaneously putting the solar radiation and the solar module temperature as input values into the solar simulation model.

The data obtained in this manner are applied to Equations 5 and 6 to calculate the normalized voltage (V_{NORM}) and current (I_{NORM}) in fault detection model of the pre-processing unit.

In Equations 5 and 6, V_{MPP,F} and I_{MPP,F} are the second maximum power point voltage and the second maximum power point current measured in the actual solar system, and V_{MPP,N} and I_{MPP,N} are the first maximum power point voltage and the first maximum power point current obtained by the photovoltaic simulation model. The normalized voltage (V_{NORM}) and current (I_{NORM}) obtained through Equations 5 and 6 may be put into machine learning (e.g., K-Nearest Neighbor, k-NN)-based fault diagnosis model for learning in Pre-Processing to diagnose a fault.

The photovoltaic panel fault diagnosis apparatus according to an embodiment of the present disclosure provides an algorithm for diagnosing a fault only with the maximum power point voltage (Vₘₚₚ) and maximum power point current (Iₘₚₚ) in the actual photovoltaic system based on the photovoltaic simulation model. To this end, a simulation model is developed using the parameter estimation method to obtain the same value as the output value of the actual photovoltaic system.

Furthermore, in order to make a robust fault diagnosis algorithm in any environment, various fault scenarios is selected and the fault data obtained through the simulation model is normalized using Equations 5 and 6. The normalized data is used as input data to a machine learning (e.g., K-Nearest Neighbor, k-NN)-based fault diagnosis model for training.

After this pre-processing, the photovoltaic panel fault diagnosis apparatus receives the solar radiation quantity and solar module temperature from the actual photovoltaic system 100 and put them as input values in the simulation model to obtain the steady-state maximum power point voltage (V_{MPP,N}) and the steady-state maximum power point current (I_{MPP, N}).

When values obtained by normal from the actual photovoltaic system are obtained, and after the maximum power point voltage (Vₘₚₚ) and maximum power point current (Iₘₚₚ) are normalized with equation 5 and equation 6 and the normalized data is inputted to the machine learning-based fault diagnosis model, the photovoltaic panel fault diagnosis apparatus can perform the diagnose process to indicate the type of photovoltaic panel fault. The photovoltaic panel fault diagnosis apparatus may include a fault alarm unit 500 to inform a fault type of PV panels.

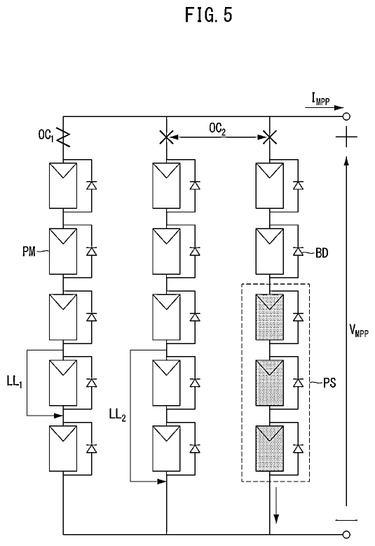

FIG. 5 is a schematic diagram illustrating a photovoltaic system simulation model of a 5×3 structure as a test bed to which an algorithm of a photovoltaic panel fault diagnosis apparatus according to an embodiment of the present disclosure is applied and fault types of the simulation model.

With reference to FIG. 5, the simulation model can be modeled to include a structure in which 5 PV modules are connected in series to form one series circuit, and 3 series circuits are connected in parallel with each other. A bypass diode (BD) may be connected in parallel to each PV module (PM).

Further, the simulation model can be modeled to have a fault type corresponding to at least one of a line-to-line short circuit fault with one line-to-line fault (LL₁), a line-to-line short circuit fault with two line-to-line fault (LL₂), an open circuit fault with one open circuit fault (OC₁), an open circuit fault with two open circuit fault (OC₂), and a partial shading (PS). The partial shading is applied to three shaded PV modules.

The maximum power point voltage (Vₘₚₚ) and the maximum power point current (Iₘₚₚ) of the simulation model may be obtained in a normal state and a faulty state by applying various fault scenarios in Table 1 to this test bed.

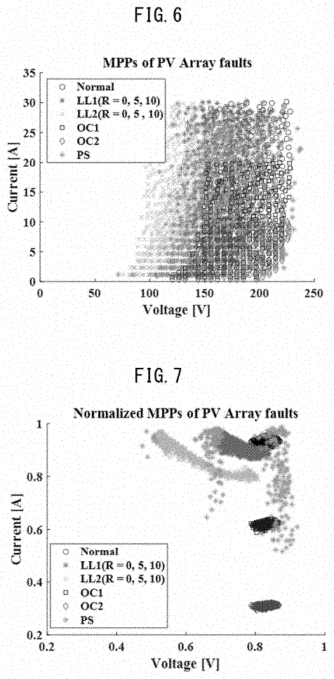

FIG. 6 is a graph of normal and faulty maximum power point voltages and normal and faulty maximum power point currents for various fault scenarios of Normal, LL1, LL2, OC1, OC2 and PS before normalization process at the photovoltaic panel fault diagnosis apparatus according to an embodiment of the present disclosure.

With reference to FIG. 6, the generated data are shown as normal and faulty maximum power point voltage (Vₘₚₚ) data and normal and faulty maximum power point current (Iₘₚₚ) data for various fault scenarios before normalization process at the photovoltaic panel fault diagnosis apparatus.

It can be seen that data before normalization process is not suitable, for making input data of a machine learning model because not only the normal state data but also all faulty state data overlap.

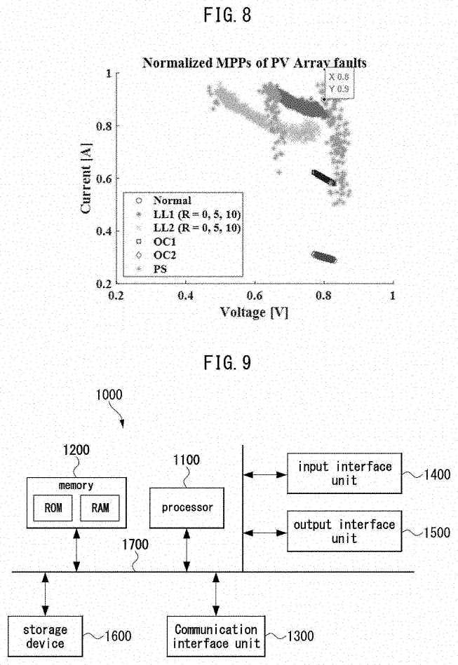

The results of the existing method of normalization using Equations 1 and 2 can be shown in FIG. 7. Meanwhile, the results of the proposed method of normalization using Equations 5 and 6 can be shown in FIG. 8. The existing method needs to obtain the open circuit voltage (V_{OC,N}) and the short circuit current (I_{SC,N}) in the normal state, and for this, several devices are required. Experimental results are described hereinafter with reference to FIGS. 7 and 8.

FIG. 7 is a graph of normal and faulty maximum power point voltage (Vₘₚₚ) data and normal and faulty maximum power point current (Iₘₚₚ) data for various fault scenarios after normalization through the conventional method.

With reference to FIG. 7, it can be seen that there is an overlap between the normal state (Normal) and the line-to-line short circuit fault (LL1, R=0, 5, 10). This causes degradation of the accuracy of the machine learning model and the accuracy of the actual fault diagnosis.

FIG. 8 is a graph of normal and faulty maximum power point voltage (Vmpp) and maximum power point current (Impp) data for various fault scenarios after normalization through a photovoltaic panel fault diagnosis method according to an embodiment of the present disclosure.

With reference to FIG. 8, in the case of the normal state (Normal), the normalized voltage (V_{NORM}) converges to 0.8 and the normalized current (I_{NORM}) to 0.9, and there is no overlap with the line-to-line short circuit fault (LL1, R=0, 5, 10).

The test data may be applied using the normalized machine learning (e.g., K-Nearest Neighbor, k-NN)-based fault diagnosis model of the photovoltaic panel fault diagnosis method according to an embodiment of the present disclosure, and the results are shown in Table 2.

Table 2 shows the machine learning-based fault detection model training accuracy and test accuracy.

TABLE 2

| | | | Machine Learning-Based Algorithm Results | |
|---|---|---|---|---|
| | | | | Fault |
| | | | | Classification |
| Fault Name | Details of Fault | | Environment Variable | Accuracy |
| Normal | Normal | | Solar Radiation Range | 100% |
| LL1 | 1 Module, | R = 0 [Ω] | From 0[W/M2] to 1000[W/M2], | 100% |
| | Line-to-line | R = 5 [Ω] | in intervals of 40[W/M2] | 100% |
| | Short Circuit | R = 10 [Ω] | Temperature Range | 100% |
| LL2 | 2 Modules, | R = 0 [Ω] | From 10° C. to 60° C., in | 100% |
| | Line-to-line | R = 5 [Ω] | intervals of 5° C. | 100% |
| | Short Circuit | R = 10 [Ω] | Total 2475 Training Data | 100% |
| OC1 | 1 Module Open | | | 100% |
| | Circuit Fault | | | |
| OC2 | 2 Modules Open | | | 100% |
| | Circuit Fault | | | |
| Normal(New) | Normal | | Solar Radiation Range | 100% |
| LL1(New) | 1 Module, | R = 3.75 [Ω] | 375, 575, 775 [W/M2] 3 values | 100% |
| | Line-to-line | R = 8.75 [Ω] | Temperature Range | 100% |
| | Short Circuit | R = 13.75 [Ω] | 0, 27.5, 67.5° C., 3 values | 100% |
| LL2(New) | 2 Modules, | R = 3.75 [Ω] | Total 81 Test Data | 100% |
| | Line-to-line | R = 8.75 [Ω] | | 100% |
| | Short Circuit | R = 13.75 [Ω] | | 88.88% |

| | | |
|---|---|---|
| OC1(New) | 1 Module Open | 100% |
| | Circuit Fault | |
| OC2(New) | 2 Modules Open | 100% |
| | Circuit Fault | |

A total of 2475 pieces of learning data are generated and used by a combination of various fault scenarios and environmental variables (solar radiation, temperature) for the photovoltaic panel fault diagnosis method according to an embodiment of the present disclosure.

The partial shadow fault is not used to train the fault diagnosis model. This is because most of the partial shade faults are temporary faults and, when a fault is diagnosed in the actual photovoltaic system and the fault type is changed in a time interval (e.g., 1 hour), it may be determined that there is a temporary partial shade and the fault can be regarded as shade fault when diagnosing the fault.

Overfitting may be prevented by using the 25% holdout validation method when learning the fault diagnosis model among a total of 2475 pieces of data without partial shade fault data. For the model type, the weighted k-nearest neighbor algorithm (K-Nearest Neighbor, k-NN) may be used, the number of neighbors k may be 10, Euclidean may be used as a distance measurement method, and a square reciprocal may be used as a distance weight.

As shown in Table 2, the result of the photovoltaic panel fault diagnosis method according to an embodiment of the present disclosure shows the model accuracy of 100% in all fault types. In addition, as for the test data, a total of 81 pieces of data may be generated by selecting an environment type and fault type different from the previously learned data.

When the fault was diagnosed using the fault diagnosis model, almost all fault diagnoses and classifications were successful. However, when the resistance is 13.75 [Ω] in the LL2 fault, the fault diagnosis model incorrectly classified it as LL1 fault. As a result, the photovoltaic panel fault diagnosis method according to an embodiment of the present disclosure reduces the cost of diagnosing a fault and diagnoses the fault type of a photovoltaic panel fault with high accuracy.

FIG. 9 is a block diagram illustrating a photovoltaic panel fault diagnosis apparatus 1000 according to an embodiment of the present disclosure.

With reference to FIG. 9, the photovoltaic panel fault diagnosis apparatus 1000 according to an embodiment of the present disclosure may include a processor 1100, a memory 1200, a transceiver 1300, an input interface device 1400, an output interface device 1500, a storage device 1600, and a bus 1700.

The photovoltaic panel fault diagnosis apparatus 1000 of the present disclosure may include at least one processor 1100 and a memory 1200 storing instructions for instructing the at least one processor 1100 to perform at least one step.

The processor 1100 may refer to a central processing unit (CPU), a graphics processing unit (GPU), or a dedicated processor on which the methods according to embodiments of the present disclosure are performed.

Each of the memory 1200 and the storage device 1600 may be configured as at least one of a volatile storage medium and a non-volatile storage medium. For example, the memory 1200 may be configured as at least one of read-only memory (ROM) and random access memory (RAM).

The photovoltaic panel fault diagnosis apparatus 1000 may also include a transceiver 1300 for communication through a wireless network.

The photovoltaic panel fault diagnosis apparatus 1000 may further include an input interface device 1400, an output interface device 1500, and a storage device 1600.

In addition, the components included in the photovoltaic panel fault diagnosis apparatus 1000 may each be connected to a bus 1700 to communicate with each other.

The photovoltaic panel fault diagnosis apparatus of the present disclosure may be implemented as a communicable desktop computer, a laptop computer, a notebook, a smart phone, a tablet personal computer (PC), a mobile phone, a smart watch, a smart glass, an e-book reader, a portable multimedia player (PMP), a portable game console, a navigation device, a digital camera, a digital multimedia broadcasting (DMB) player, a digital audio recorder, a digital audio player, digital video recorder, digital video player, a personal digital assistant (PDA), etc.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A method for diagnosing photovoltaic panel fault, the method comprising:
acquiring insolation of the photovoltaic system and temperature of the photovoltaic module;
obtaining first data including a maximum power voltage in a steady state and a maximum power current in a steady state by inputting the amount of solar radiation and the temperature of the photovoltaic module into a simulation model;
obtaining second data including a real-time maximum power voltage and a real-time maximum power current through maximum power point tracking of the photovoltaic system;
normalizing the second data by utilizing the first data; and
diagnosing a fault type of the photovoltaic system by inputting the normalized data into a fault diagnosis model.

2. The method of claim 1, further comprising:
generating the simulation model, wherein the generating of the simulation model comprises selecting a one-diode model that reduces the difference between the I-V characteristic curve value of the actual solar module and the I-V characteristic curve value of the simulation model; and
performing parameter estimation for a series resistance and a parallel resistance in an equivalent circuit of an actual photovoltaic device including the series resistance and the parallel resistance connected to the one-diode model.

3. The method of claim 1, wherein the obtaining of the first data is performed to obtain based on a fault condition of a predetermined fault scenario for the photovoltaic system through the simulation model.

4. The method of claim 3, wherein the fault condition includes solar radiation at intervals of several tens W/m² in the range of 0 to 1,000 W/m² and solar module temperatures at predetermined temperature intervals in the range of 10° C. to 60° C.

5. The method of claim 3, wherein the obtaining of the normalized data utilizes a maximum power voltage and a maximum power current obtained from maximum power point tracking through a converter installed in the photovoltaic system.

6. The method of claim 5, wherein the obtaining of the normalized data includes:
obtaining a normalized voltage by dividing the maximum power voltage by an open circuit voltage in a steady state of the photovoltaic system; and
obtaining a normalized current by dividing the maximum power current by a short circuit current in a normal state of the photovoltaic system.

7. The method of claim 6, further comprising generating the fault diagnosis model through machine learning based on the normalized voltage and the normalized current calculated according to a preset fault scenario for the photovoltaic system.

8. An apparatus for diagnosing photovoltaic panel fault, the apparatus comprising:
a processor; and
a memory configured to store a program command executed by the processor,
wherein, when the program command is executed by the processor, the program command is executed such that the processor performs:
acquiring insolation of the photovoltaic system and temperature of the photovoltaic module; obtaining first data including a maximum power voltage in a steady state and a maximum power current in a steady state by inputting the amount of solar radiation and the temperature of the photovoltaic module into a simulation model;
obtaining second data including a real-time maximum power voltage and a real-time maximum power current through maximum power point tracking of the photovoltaic system;
normalizing the second data by utilizing the first data; and
diagnosing a fault type of the photovoltaic system by inputting the normalized data into a fault diagnosis model.

9. The apparatus of claim 8, wherein the processor further performs generating the simulation model, wherein the generating of the simulation model comprises:
selecting a one-diode model that reduces the difference between the I-V characteristic curve value of the actual solar module and the I-V characteristic curve value of the simulation model; and
performing parameter estimation for a series resistance and a parallel resistance in an equivalent circuit of an actual photovoltaic device including the series resistance and the parallel resistance connected to the one-diode model.

10. The apparatus of claim 8, wherein the obtaining of the first data is performed to obtain based on a fault condition of a predetermined fault scenario for the photovoltaic system through the simulation model.

11. The apparatus of claim 10, wherein the fault condition includes solar radiation at intervals of several tens W/m² in the range of 0 to 1,000 W/m² and solar module temperatures at predetermined temperature intervals in the range of 10° C. to 60° C.

12. The apparatus of claim 10, wherein the obtaining of the normalized data utilizes a maximum power voltage and a maximum power current obtained from maximum power point tracking through a converter installed in the photovoltaic system.

13. The apparatus of claim 12, wherein the obtaining of the normalized data includes:
obtaining a normalized voltage by dividing the maximum power voltage by an open circuit voltage in a steady state of the photovoltaic system; and
obtaining a normalized current by dividing the maximum power current by a short circuit current in a normal state of the photovoltaic system.

14. The apparatus of claim 13, wherein the processor further performs generating the fault diagnosis model through machine learning based on the normalized voltage and the normalized current calculated according to a preset fault scenario for the photovoltaic system.

15. An apparatus for diagnosing photovoltaic panel fault, the apparatus comprising:
a processor; and
a memory configured to store at least one instruction executed by the processor,
wherein the at least one instruction is executed by the processor to perform:
modeling a photovoltaic system simulation model necessary for the fault diagnosis algorithm;
defining fault scenarios and pre-processing through data normalization after creating and acquiring fault data in advance using the photovoltaic system simulation model; and
utilizing scenario-specific fault data obtained through the data normalization with a machine learning method.

16. The apparatus of claim 15, wherein the processor further performs selecting a one-diode model using one diode as a photovoltaic power generation module simulation model similar to the actual photovoltaic system using a model-based fault diagnosis algorithm.

17. The apparatus of claim 15, wherein the processor further performs using a parameter estimation method to improve accuracy of the simulation model by reducing an error between a current-voltage (I-V) characteristic curve value of the actual photovoltaic module and an I-V characteristic curve value of the simulation model.

18. The apparatus of claim 15, wherein the processor further performs estimating a series resistance and a parallel resistance, and creating and acquiring fault data with the photovoltaic module simulation model obtained through parameter estimation.

19. The apparatus of claim 15, wherein the processor further performs determining a fault scenario in advance to generate fault data,

20. The apparatus of claim 19, wherein the fault scenario is based on consideration of various fault conditions including a range of solar radiation from 0 W/M² to 1,000 W/M², 40 W/M² intervals and temperature of 10° C. to 60° C., 5° C. intervals, and input as an input value to a photovoltaic simulation to output data, which normalized for use in the fault diagnosis.
